(19) United States
(12) Patent Application Publication
(10) Pub. No.: US 2010/0031990 A1
(43) Pub. Date: Feb. 11, 2010

(54) Cascaded Photovoltaic and Thermophotovoltaic Energy Conversion Apparatus with Near-Field Radiation Transfer Enhancement at Nanoscale Gaps

(75) Inventors: Mathieu Francoeur, Lexington, KY (US); Rodolphe Vaillon, Lyon (FR); M. Pinar Menguc, Lexington, KY (US)

Correspondence Address: CROWELL & MORING LLP;INTELLECTUAL PROPERTY GROUP, P.O. BOX 14300, WASHINGTON, DC, 20044-4300, US

(73) Assignee: University of Kentucky Research Foundation, Lexington, KY (US)

(21) Appl. No.: 12/534,322

(22) Filed: Aug. 3, 2009

Related U.S. Application Data
(60) Provisional application No. 61/137,692, filed on Aug. 1, 2008.

(51) Int. Cl. H01L 35/00; H01L 21/50

(52) U.S. Cl. 136/206; 438/55; 257/E21.499

(57) ABSTRACT

A cascaded photovoltaic/thermophotovoltaic energy conversion apparatus, a cascaded thermophotovoltaic energy conversion apparatus, and a method for forming the apparatuses are provided. The cascaded photovoltaic/thermophotovoltauc apparatus includes a photovoltaic device that receives solar radiation on an upper surface thereof and produces a first electric current output and a thermal radiation output, and a thermophotovoltaic device disposed a predetermined distance below a lower surface of the photovoltaic device, the thermophotovoltaic device receiving the thermal radiation output and converting the received thermal radiation output into a second electric current output. The cascaded thermophotovoltaic apparatus includes a radiator maintained at constant temperature via an external heat input on its upper surface and produces a thermal radiation output, and a thermophotovoltaic device disposed a predetermined distance below a lower surface of the radiator, the thermophotovoltaic device receiving the thermal radiation output and converting the received thermal radiation output into a first electric current output.

The present application claims priority under 35 U.S.C. § 119 to U.S. Provisional Application No. 61/137,692, filed Aug. 1, 2008, the entire disclosure of which is herein expressly incorporated by reference.

### BACKGROUND OF THE INVENTION

The present invention relates to photovoltaic and thermophotovoltaic devices. More specifically, the invention provides an energy conversion apparatus with a cascaded arrangement of photovoltaic (PV) and thermophotovoltaic (TPV) devices or a cascaded arrangement of TPV devices that uses near-field radiation enhancement. The invention also provides a method for forming the cascaded arrangements.

TPV power generation involves conversion of terrestrial thermal radiation into electricity using PV cells, as opposed to direct conversion of solar radiation into electricity. PV cells used in TPV devices work the same way as cells used for direct solar energy conversion, but are usually referred as TPV cells. Although TPV and PV cells refer to the same thing, cells in TPV systems usually require a junction with lower bandgap (discussed in section 2.6), thus explaining the distinction made in the literature.

A schematic representation of a TPV device is shown in FIG. 1. TPV power generators work as follows. A radiator or emitter 10, which is used as a source of heat applied to a TPV cell, is maintained at fixed temperature Tᵣ. Heat input for TPV devices can come from many sources such as the sun, combustion in a micro-chamber, or high-temperature waste heat from industrial processes. In fact, any sources of heat can be used, depending on the environment and purpose of the TPV devices. Typical operating temperatures of radiators are between 1000 and 2000 K, but TPV systems can also work with lower radiator temperatures. The radiator 10 emits thermal radiation through vacuum 11, of thickness “d”, toward the TPV cells (p-n or n-p junction) which converts photons having energy higher than the bandgap of TPV cells into electricity. As illustrated in FIG. 1, TPV cells include a p- or n-doped region 12, a depletion region 13/14, and an n- or p-doped region 15. The different zones shown in FIG. 1 are not representative of the actual sizes. TPV devices are attractive due to the fact that they do not involve any moving parts, they are portable, they provide silent operation, and they potentially have low maintenance costs. In addition, different mechanisms of heat input is versatile and not limited to solar irradiation.

In addition to the elements illustrated in FIG. 1, a TPV system also typically includes a recirculation system for photons with energy that does not match the bandgap of TPV cells, a cooling device, and a power conditioning system.

Photons emitted by the radiator with energy less than the bandgap of the TPV cells or larger than the bandgap can contribute to the deterioration of TPV cells performances by transferring their energy into heat. Consequently, a key requirement for the operation of TPV systems is the effective use of radiative energy that is not useful for energy conversion. The idea is to send back these photons toward the radiator using filters or back-reflectors.

It is also necessary to use a cooling device to maintain the TPV cells around room temperature (300 K) to ensure optimum efficiency of the system. A power conditioning system is necessary to maintain the radiator and TPV cells at constant temperatures, and for the management of the electrical power output.

Current TPV power generators have two main drawbacks: (1) low energy conversion efficiency, and (2) low power output.

The conversion efficiency (or sometimes referred as thermal efficiency) is defined as the ratio of electric power generated from a TPV cell to the entire spectrum of radiative power absorbed. Since thermal radiation is a broadband phenomenon (i.e., emission for a wide spectral band), selective filters with high transmittance around the bandgap of the TPV cells and high reflectance for other frequencies can be placed between the radiator and TPV cells, and then increase the conversion efficiency of the TPV system. Another way to increase the conversion efficiency is to use selective emitters with high emissivity for selected wavelengths. Periodic structures, such as 1D, 2D, and 3D photonic crystals, can lead to high emissivity of the radiator for a given wavelength (around the bandgap of TPV cells) and low emissivity for other frequencies. These kinds of structures use the benefits of wave interferences in thin films for selective emission of thermal radiation in a narrow spectral band. Other structures such as gratings can be employed for selective emission of thermal radiation, where surface polaritons are excited via the periodicity of the surface, leading to thermal emission in narrow spectral bands.

All the techniques mentioned above show an improved energy conversion efficiency, since photons that do not participate in the energy conversion are either reflected back (via filters) or not emitted by the radiator (via a selective emission process). On the other hand, none of these techniques can actually increase the power output of TPV devices. To increase the power output, while maintaining the operating radiator temperature in the same range, it is necessary to use the near-field effects of thermal radiation. This can be done by spacing the radiator and the TPV cells by a distance of a few nanometers; this is discussed next.

Nanoscale-gap TPV devices, i.e., devices with a nano-size gap between the radiator and TPV cells, can benefit from radiation tunneling by spacing the radiator and TPV cells in such a way that the surface of the TPV cells lays in the evanescent wave field of the radiator.

Specifically, any body at temperature greater than 0 K emits thermal radiation with near- and far-field components. Waves emitted in the far-field are propagating and taken into account in the classical theory of thermal radiation based on the Planck blackbody distribution. The near-field component refers to evanescent waves that do not propagate in the far-field, but rather decay exponentially over a distance of about a wavelength normal to an emitting surface. Surface polaritons are evanescent waves generated by collective oscillations of charges within a material. These evanescent waves can interact with another body only if its surface lays in the evanescent field of the emitting medium; this phenomenon is called radiation tunneling. The overall consequence is that radiative heat transfer in the near-field can exceed, by several orders of magnitude, the values predicted by Planck's distribution due to tunneling of evanescent waves.

To take advantage of the evanescent wave field of the radiator, nanoscale-gap TPV devices employ a gap on the order of a few tens of nanometers between the radiator and TPV cells. The radiative heat flux incident on TPV cells, which is strictly due to propagating waves for regular TPV systems (far-field regime of thermal radiation), becomes a combination of propagating and evanescent modes for nanoscale-gap TPV devices (near-field regime of thermal radiation). Therefore, by using the same amount of energy for the heat input, it is possible to increase the electric power output of TPV systems by using the near-field effects of thermal radiation. Moreover, if the radiator can support surface polaritons, radiant energy exchanges can take place in a very narrow spectral range.

It is also important to note that in nanoscale-gap TPV applications, a vacuum gap is preferred over a gas or a solid gap in order to avoid heat conduction between the radiator and TPV cells. To summarize, near-field effects of thermal radiation fulfill the two main drawbacks of TPV devices, by selective emission of thermal radiation in a narrow spectral band (via thermal excitation of surface polaritons), and by potentially increasing the electrical power output of the device (via radiation tunneling).

### SUMMARY OF THE INVENTION

The present invention provides an improvement over prior art photovoltaic/thermophotovoltaic (PV/TPV) devices, by providing a cascaded photovoltaic energy conversion apparatus that has increased efficiency and a method for forming such an apparatus. The apparatus is configured to take advantage of near-field radiation output from a PV device by arranging such a device within a predetermined distance of the TPV device. The PV device and the TPV device in the cascaded arrangement both provide an electric current output, and the TPV device removes excess thermal energy from the PV device, thereby cooling the PV device and increasing the efficiency of the PV/TPV energy conversion apparatus. The same approach can also be used in a cascaded TPV apparatus, where the first layer is a radiator maintained at fixed temperature via some external heat input instead of a PV layer.

Other objects, advantages, and novel features of the present invention will become apparent from the following detailed description of the invention when considered in conjunction with the accompanying drawings.

### BRIEF DESCRIPTION OF THE DRAWINGS

FIG. 1 illustrates a schematic representation of a TPV device;

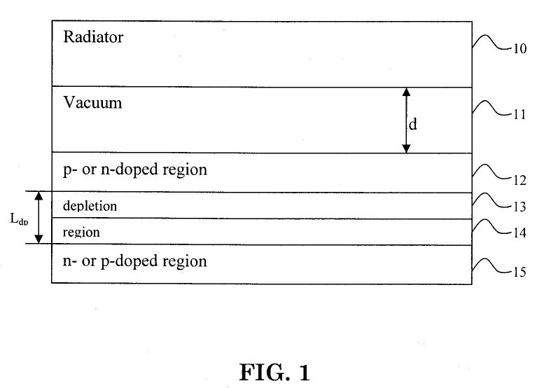

FIG. 2 illustrates an exemplary embodiment of a PV and TPV energy conversion apparatus in accordance with the present invention;

FIG. 3 illustrates an exemplary embodiment of a method of forming a cascaded PV/TPV energy conversion apparatus in accordance with the present invention;

FIG. 4 illustrates an exemplary embodiment of a PV and TPV energy conversion apparatus that includes a plurality of TPV devices in accordance with the present invention (cascaded PV/TPV device); and

FIG. 5 illustrates another exemplary embodiment of a full TPV energy conversion apparatus that includes a plurality of TPV devices in accordance with an exemplary embodiment of the present invention (cascaded TPV device where the first layer is a radiator).

### DETAILED DESCRIPTION OF THE EXEMPLARY EMBODIMENTS

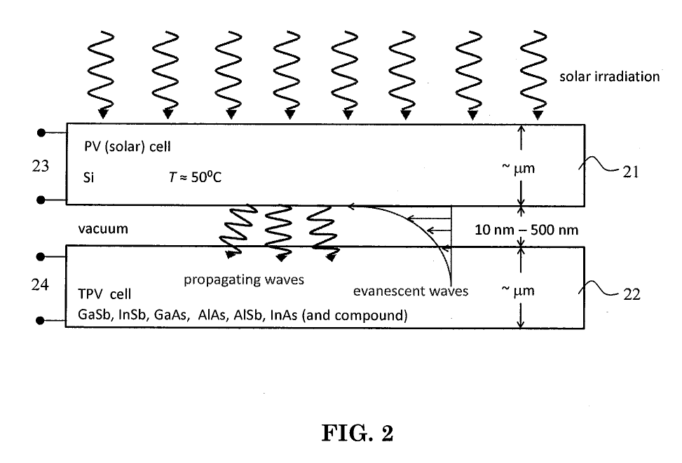

According to the present invention, heat losses in photovoltaic (PV) cells are recycled by using a nanoscale-gap thermophotovoltaic (TPV) device. A schematic representation of an exemplary cascaded PV/TPV apparatus is shown in FIG. 2.

As shown in FIG. 2, solar radiation is incident on PV cell (or alternatively called a solar cell or PV device) 21. Part of the solar spectrum is used by the PV cell 21 to generate electricity (photocurrent) at output terminals 23. The other part of the spectrum does not contribute to electricity generation, and absorption of this radiation increases the temperature of the cell. Moreover, the part of the solar spectrum that is used to generate electricity also leads to an increase of the cell temperature. Elevation of the PV cell temperature decreases its efficiency in generating electricity. Typically, this increased temperature is viewed as the reason for wasted energy and additional techniques are employed to remove the excess heat from the PV cell.

It has been recognized that increased temperature that is normally considered as waste energy can be used to generate additional electricity using a TPV cell. Specifically, as depicted in FIG. 2, a TPV cell (TPV device) 22 is placed in close proximity (e.g., 10-500 nanometers) of the PV cell 21 in order to cool down the PV cell 21 and thus generate more electricity via the TPV cell 22 at output terminals 24. The system according to the present invention has three main advantages: (1) the PV cells are cooled down without spending energy (e.g., via a forced convection cooling system), (2) since the PV cell is cooled down, the efficiency for photocurrent generation by the PV cell is increased, and (3) the extra energy present in the PV cell (dissipated into thermal energy, which leads to an increase of the TPV cell temperature) is recycled in order to generate more electricity via the TPV cells. Therefore, the TPV cell shown in FIG. 2 is used as a heat sink and also as a device to generate electricity. The cascaded PV/TPV device according to the present invention can significantly improve efficiencies of solar energy conversion.

The purpose of a traditional PV cell is to absorb solar radiation and convert it into photocurrent (i.e., electricity). However, only photons with energy equal to or higher than the so-called bandgap of the PV cell can be used to generate electricity. Briefly, the bandgap can be defined as the minimum energy needed for an electron to pass from the valence band toward the conduction band. When this happens, free electrons in the conduction band can potentially be used to generate electricity. Typical PV cells are generally made of silicon (Si) with thicknesses of a few tens of microns. The energy bandgap of Si PV cells is about 1.1 eV, which corresponds to a wavelength of about 1.1 μm. This means that solar/radiative energy with wavelength smaller than 1.1 μm can be used to generate photocurrent, while those with wavelengths greater than 1.1 μm contribute only to raise the temperature of the PV cell via absorption by the lattice and free carriers. Note that photons contributing to generate photocurrent also contribute to increase TPV cell temperature via thermalization. The sun can be approximated as a blackbody at 6000 K, such that its peak wavelength is about 0.5 μm.

According to the classical theory of thermal radiation, no material/body can emit or absorb more radiation than a blackbody. This is true for far-field arrangements when bodies exchanging thermal radiation are separated by distances greater than the dominant wavelength emitted. When two bodies exchanging thermal radiation are in the near-field, thermal radiation can exceed, by several orders of magnitude, the values predicted for blackbodies. As shown in FIG. 2, this is due to the tunneling of evanescent waves from the emitter to the receiver. These waves do not propagate in the far-field and decay exponentially over a distance of about a wavelength normal to the surface of an emitting material. Therefore, when bodies exchanging thermal radiation are in the evanescent fields of each other, radiation transfer also occurs via evanescent waves, a phenomenon called radiation tunneling. Note that as depicted in FIG. 2, radiation transfer also occurs via propagating waves, which are the type of waves that are accounted for in the classical theory of thermal radiation.

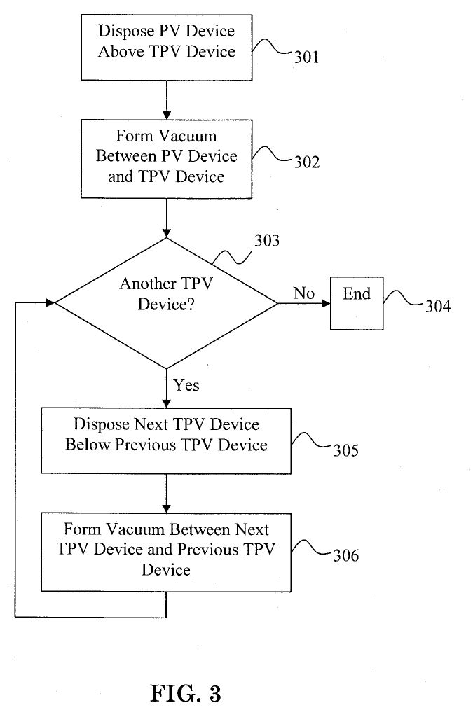

FIG. 3 illustrates an exemplary embodiment of a method of forming a cascaded PV/TPV energy conversion apparatus in accordance with the present invention. According to the method, in step 301, a PV device, which is configured to receive light radiation on an upper surface thereof and produce a first electric current output and a first thermal radiation output, is disposed a first predetermined distance above a first TPV device that receives the first thermal radiation output and converts the received first thermal radiation output into a second electric current output. The first thermal radiation output includes a near-field component and a far-field component. The method described in FIG. 3 is also applicable to a cascaded TPV system, where the first layer is a radiator maintained at constant temperature via an external heat source instead of a PV cell.

In step 302, a vacuum is formed between the first PV device and the first TPV device. For the range of temperatures considered, the optimal separation distance between the PV cell and TPV cell should be within the 10-500 nm range. However, due to fabrication, surface roughness, and the like, it may be preferable to use vacuum gaps between 50-500 nm. In an exemplary embodiment of the present invention, the predetermined distance (i.e., vacuum gap) is between 50-100 nm. A layer of metallic nanoparticles (such as gold or silver) can also be deposited on the surface of the TPV cell. The purpose of these particles is to increase thermal radiation absorption by the TPV cell at selected wavelengths via surface plasmon resonance. Nanoparticles deposition can be performed in various ways. In step 303, it is determined whether another TPV device is to be included in the cascaded arrangement. If only one TPV device is to be included, the process ends at step 304.

The particular choice of materials for the TPV cells depends on the operating temperature of the system (and, of course, on the availability and cost of the materials). The temperature of the PV cell to be around 50° C. (323 K), so that the peak wavelength of radiation emission would be around 9 μm (corresponding to an energy of about 0.14 eV). GaSb at room temperature has an energy bandgap of 0.72 eV, which is too high for the temperature of the radiator (i.e., PV cell). Therefore, a ternary alloy made of GaSb and indium antimonide (InSb), In₁₋ₓGaₓSb, which has a variable bandgap (range 0.17-0.72 eV at room temperature) depending on the proportion of GaSb and InSb may be used. Other materials (and their ternary or quaternary alloys), such as aluminum arsenide (AlAs), aluminum antimonide (AlSb), indium arsenide (InAs), and gallium arsenide (GaAs) may also be used.

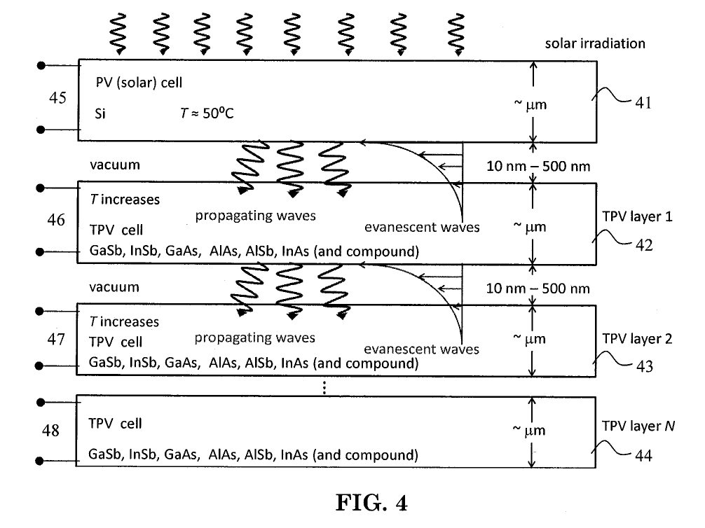

The cascaded PV/TPV system shown in FIG. 2 contains only one TPV layer. However, the TPV cell can also heat up, and therefore another TPV cell can be added below. In fact, N TPV layers (42, 43, 44) can be added below the PV cell 41, as shown in FIG. 4. Each of the PV cell and the TPV cells, respectively, produce an electric output at output terminals 45, 46, 47, 48. Of course, the optimal number of layers will be based upon the particular materials used, etc., in order to optimize and balance cost and efficiency of the system.

According to another exemplary embodiment of a method of the invention, a plurality of TPV layers (devices) are disposed below the PV device, a vacuum is formed between each of the adjacent layers, and each of the layers produces a thermal output and an electric current output. As illustrated in FIG. 3, if it is determined in step 303 that another TPV device is to be included in the cascaded photovoltaic energy conversion apparatus, then in step 305 the next TPV device is disposed below the previous TPV device in the cascaded arrangement. In step 306, a vacuum is formed between the next TPV device and the previous TPV device. These steps can be repeated as many times as necessary for each of the TPV devices. Although FIG. 3 illustrates the formation of a vacuum between each successive layer in the cascaded arrangement prior to the addition of another TPV device, the entire cascaded arrangement can be formed first followed by the formation of the vacuum(s). Each of the multiple layers provides another level of increased efficiency for the cascaded PV/TPV device.

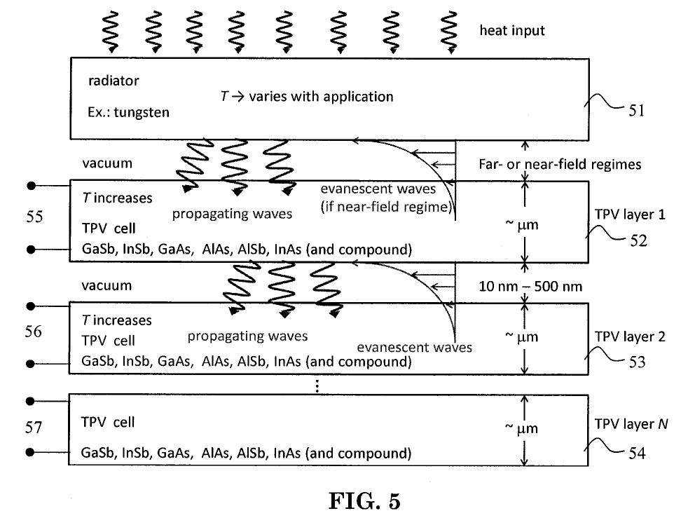

Although the systems discussed above use the sun as a heat input, the cascaded system of the present invention could also be used with a radiator as the heat input (i.e., cascaded TPV system). As illustrated in FIG. 5, a radiator (such as tungsten) 51 is used to emit thermal radiation toward a first TPV cell 52. The radiator and first layer of TPV cells can be in the near-field regime or not. As for the PV system, one (or N) layer(s) 53, 54 are located below the first TPV cell 52 (in the near-field) in order to generate electricity and cool down the first layer. Each of the PV cell and the TPV cells, respectively, produce an electric output at output terminals 55, 56, 57.

As described above, the cascaded PV/TPV and cascaded TPV devices according to the present invention provide improved efficiency over prior art PV and TPV devices. Accordingly, the present invention has significant advantages over the prior art.

The exemplary cascaded PV/TPV and cascaded TPV systems can be used as power sources for MEMS devices, energy sources in transportation, stand-alone gas furnaces, power systems for navigation of sailing boats, silent power supplies on recreational vehicles, co-generation of electricity and heat, remote electricity generators, transportation cogeneration, electric-grid independent appliances, aerospace and military power supplies, to name only a few.

While the invention has been described in connection with various embodiments, it will be understood that the invention is capable of further modifications. This application is intended to cover any variations, uses or adaptation of the invention following, in general, the principles of the invention, and including such departures from the present disclosure as, within the known and customary practice within the art to which the invention pertains.

The foregoing disclosure has been set forth merely to illustrate the invention and is not intended to be limiting. Since modifications of the disclosed embodiments incorporating the spirit and substance of the invention may occur to persons skilled in the art, the invention should be construed to include everything within the scope of the appended claims and equivalents thereof.

What is claimed is:

1. A cascaded photovoltaic/thermophotovoltaic energy conversion apparatus, comprising:
a photovoltaic device with an upper surface that receives solar radiation and a lower surface that produces a first thermal radiation output, the photovoltaic device producing a first electric current output; and
a first thermophotovoltaic device disposed a first predetermined distance below the lower surface of the photovoltaic device, the first thermophotovoltaic device receives the first thermal radiation output and converts the received first thermal radiation output into a second electric current output.

2. The cascaded photovoltaic/thermophotovoltaic energy conversion apparatus of claim 1, wherein a vacuum is formed between the photovoltaic device and the first thermophotovoltaic device.

3. The cascaded photovoltaic/thermophotovoltaic energy conversion apparatus of claim 1, wherein the first predetermined distance between the photovoltaic device and the first thermophotovoltaic device is between 10 nm and 500 nm.

4. The cascaded photovoltaic/thermophotovoltaic energy conversion apparatus of claim 3, wherein the first predetermined distance between the photovoltaic device and the first thermophotovoltaic device is between 50 nm and 100 nm.

5. The cascaded photovoltaic/thermophotovoltaic energy conversion apparatus of claim 1, wherein the first thermal output received by the first thermophotovoltaic device comprises a far-field component and a near-field component.

6. The cascaded photovoltaic/thermophotovoltaic energy conversion apparatus of claim 1, wherein the first thermal output received by the first thermophotovoltaic device comprises propagation waves and evanescent waves.

7. The cascaded photovoltaic/thermophotovoltaic energy conversion apparatus of claim 1, wherein the first predetermined distance between the photovoltaic device and the first thermophotovoltaic device is determined based on the analysis of the near-field thermal radiation emitted by the photovoltaic cell.

8. The cascaded photovoltaic/thermophotovoltaic energy conversion apparatus of claim 1, further comprising a second thermophotovoltaic device disposed in a cascaded arrangement a second predetermined distance below the first thermophotovoltaic device, the second thermophotovoltaic device receiving a second thermal radiation output from the first thermophotovoltaic device and converting the second thermal radiation output into a third electric current output.

9. The cascaded photovoltaic/thermophotovoltaic energy conversion apparatus of claim 8, wherein the first and second predetermined distances are between 10 nm and 500 nm.

10. The cascaded photovoltaic/thermophotovoltaic energy conversion apparatus of claim 9, wherein the first and second predetermined distances are between 50 nm and 100 nm.

11. The cascaded photovoltaic/thermophotovoltaic energy conversion apparatus of claim 1, wherein the first thermophotovoltaic device comprises at least one of GaSb, InSb, GaAs, AlAs, AlSb, and InAs.

12. The cascaded photovoltaic/thermophotovoltaic energy conversion apparatus of claim 8, wherein a first vacuum is disposed between the photovoltaic device and the first thermophotovoltaic device and a second vacuum is disposed between the first thermophotovoltaic device and the second thermophotovoltaic device.

13. The cascaded photovoltaic/thermophotovoltaic energy conversion apparatus of claim 8, wherein the first and second predetermined distances are determined based on the analysis of the near-field thermal radiation emitted by a TPV cell.

14. The cascaded photovoltaic/thermophotovoltaic energy conversion apparatus of claim 8, wherein the first and second thermophotovoltaic devices comprise at least one of GaSb, InSb, GaAs, AlAs, AlSb, and InAs.

15. The cascaded photovoltaic/thermophotovoltaic energy conversion apparatus of claim 1, further comprising a plurality of other thermophotovoltaic devices disposed in a cascaded arrangement a second predetermined distance below the first thermophotovoltaic device, each of the other thermophotovoltaic devices receiving an additional thermal radiation output and converting the additional thermal radiation output into an additional electric current output.

16. The cascaded photovoltaic/thermophotovoltaic energy conversion apparatus of claim 15, wherein a vacuum is disposed between each pair of adjacent devices in the cascaded photovoltaic/thermophotovoltaic energy conversion apparatus.

17. A method of forming a cascaded photovoltaic/thermophotovoltaic energy conversion apparatus, the method comprising the acts of:
disposing a photovoltaic device having an upper surface that receives solar radiation and a lower surface that produces a first thermal radiation output, the photovoltaic device producing a first electric current output, a first predetermined distance above a first thermophotovoltaic device that receives the first thermal radiation output and converts the received first thermal radiation output into a second electric current output; and
forming a vacuum between the photovoltaic device and the first thermophotovoltaic device.

18. The method of claim 17, further comprising the act of:
disposing a second thermophotovoltaic device a second predetermined distance below the first thermophotovoltaic device; and
forming a vacuum between the first thermophotovoltaic device and the second thermophotovoltaic device,
wherein the second thermophotovoltaic device receives a second thermal radiation output from the first thermophotovoltaic device and converts the received second thermal radiation output into a third electric current output.

19. The method of claim 17, wherein the first predetermined distance is between 10 nm and 500 nm.

20. The method of claim 17, wherein the first predetermined distance is between 50 nm and 100 nm.

21. A cascaded thermophotovoltaic energy conversion apparatus, comprising:
a radiator maintained at constant temperature via an external heat input applied at an upper surface of the radiator, the radiator having a lower surface that produces a first thermal radiation output; and
a first thermophotovoltaic device disposed a first predetermined distance below the lower surface of the radiator, the first thermophotovoltaic device receives the first thermal radiation output and converts the received first thermal radiation output into a first electric current output.

22. The cascaded thermophotovoltaic energy conversion apparatus of claim 21, wherein a vacuum is formed between the radiator and the first thermophotovoltaic device.

23. The cascaded thermophotovoltaic energy conversion apparatus of claim 21, wherein the first predetermined distance between the radiator and the first thermophotovoltaic device is between 10 nm and 500 nm.

24. The cascaded thermophotovoltaic energy conversion apparatus of claim 23, wherein the first predetermined distance between the radiator and the first thermophotovoltaic device is between 50 nm and 100 nm.

25. The cascaded thermophotovoltaic energy conversion apparatus of claim 21, further comprising a second thermophotovoltaic device disposed in a cascaded arrangement a second predetermined distance below the first thermophotovoltaic device, the second thermophotovoltaic device receiving a second thermal radiation output from the first thermophotovoltaic device and converting the second thermal radiation output into a second electric current output.

26. The cascaded thermophotovoltaic energy conversion apparatus of claim 25, wherein a first vacuum is disposed between the radiator and the first thermophotovoltaic device and a second vacuum is disposed between the first thermophotovoltaic device and the second thermophotovoltaic device.

27. A method of forming a cascaded thermophotovoltaic energy conversion apparatus, the method comprising the acts of:
disposing a radiator maintained at constant temperature via an external heat input on its upper surface, and a lower surface that produces a first thermal radiation output, a first predetermined distance above a first thermophotvoltaic device that receives the first thermal radiation output and converts the received first thermal radiation output into a first electric current output; and
forming a vacuum between the radiator and the first thermophotovoltaic device.

28. The method of claim 27, further comprising the act of:
disposing a second thermophotovoltaic device a second predetermined distance below the first thermophotovoltaic device; and
forming a vacuum between the first thermophotovoltaic device and the second thermophotovoltaic device,
wherein the second thermophotovoltaic device receives a second thermal radiation output from the first thermophotovoltaic device and converts the received second thermal radiation output into a second electric current output.

29. The method of claim 27, wherein the first predetermined distance is between 10 nm and 500 nm.

30. The method of claim 27, wherein the first predetermined distance is between 50 nm and 100 nm.
